(19) United States
(12) Patent Application Publication
(10) Pub. No.: US 2012/0038058 A1
(43) Pub. Date: Feb. 16, 2012

(54) VERTICALLY CONTACTED ELECTRONIC COMPONENT AND METHOD FOR PRODUCING SAME

(75) Inventors: Ingo Daumiller, Dettingen (DE); Ulrich Heinle, Neu-Ulm (DE); Mike Kunze, Pfaffenhofen a.d. Roth (DE); Dmitry Nikolaev, Ulm (DE)

(73) Assignee: MICROGAN GMBH, Ulm (DE)

(21) Appl. No.: 13/257,029

(22) PCT Filed: Mar. 22, 2010
(86) PCT No.: PCT/EP2010/001792

§ 371 Date: Oct. 31, 2011

(30) Foreign Application Priority Data
Mar. 20, 2009 (DE) 10 2009 014 237.1

(51) Int. Cl. H01L 23/48; H01L 21/302

(52) U.S. Cl. 257/774; 438/702; 257/E23.011; 257/E21.214

(57) ABSTRACT

An electronic component has at least one contact surface situated in a contact plane, at least one insulating layer disposed above the contact plane, at least one stabilizing layer disposed on the insulating layer for increasing a mechanical stability of the component, and at least one of a bonding contact and a soldering contact. The insulating layer and the stabilizing layer have at least one opening which opens in an upper side of the stabilizing layer. The upper side of the stabilizing layer is oriented away from the contact surface. The opening extends through the stabilizing layer and the insulating layer as far as the contact surface. The at least one of a bonding contact and a soldering contact extends over the stabilizing layer and touches the contact surface through the opening.

The invention relates to an electronic component which is vertically contactable, i.e. which is contactable via bonding and/or soldering contacts which are situated over those active regions of the component which are contacted by the corresponding contacts. The invention relates in addition to a method for the production of such a component with vertical contacting.

In the production of electronic semiconductor components, the production costs are reduced inter alia by miniaturisation of the surface geometry/chip geometry since the number of components is increased in the case of a given wafer- or substrate surface area because of the miniaturisation.

Discrete electronic components generally have two or more contacts for the electrical contacting, which contacts are connected in housings or modules with the help of different technologies, such as bonding, soldering and/or flip chip technology.

According to the type of electronic semiconductor component, the position and placing of the contacts is different. Because of the position and placing of the contacts, basically two groups of electronic semiconductor components can be formed. On the one hand, the electronic semiconductor components in which the contacting takes place both on the front-side and on the rear-side of the component (“vertical component”. The term must however be distinguished from “vertical contacting” which is possible with vertical and lateral components.) and, on the other hand, the components which must be produced on the basis of the particular property of the semiconductor material and/or their function as lateral embodiment and in which the contacts are situated in one plane, e.g. on the front-side of the component (lateral component).

Generally, the required surface of the contact zone in the active region of a component is much smaller than the bonding surface or soldering surface required for the contacting and via which the component is connected to for example a housing. The bonding surfaces or soldering surfaces for connection of the component therefore do not occupy useable substrate- or wafer surface area. In particular in the case of electronic semiconductor components having a lateral arrangement of contacts, this problem arises.

One possibility for reducing the component size or reducing the non-useable surface area is placing the bonding surfaces or soldering surfaces not laterally relative to the active zone but, with corresponding technology, directly over the active zone of the component, provided that the active zone has a sufficiently large surface area.

For example in power electronics, an electronic semiconductor component normally has a large number of similar individual components which are connected in parallel on the substrate- or wafer plane. The parallel connection of the individual components is effected by the corresponding connection and wiring of the respective contacts. In this way, several hundred individual components can be connected to form one individual component. Because of the connection together of the individual components, the surface area of the active zone is increased. As a result, a dimension is produced for the active surface which is suitable and useable for bonding surfaces or soldering surfaces on the active zone.

Vertical contactings were applied, according to the state of the art, in components (e.g. diodes or transistors) in which a high current (e.g. 10 A to 100 A) with small voltages (up to approx. 200 V) is connected. As a result of the high current, as low ohmic losses as possible due to the supply lines are required. Because of the fact that the vertical contacting sits above the active component, extremely short supply line lengths are possible (determined by the number of contact holes).

In the case of this method, the supply lines (or bonding surfaces) intersect the contacts of the component. This means that the spacing of contact to line must be so large that there is no electrical breakthrough. The spacing or breakthrough is determined by the dielectric layers.

In the case of low voltages, this is not very problematic and generally a standard passivating made of SIN is used.

In the case of high voltages, this layer must be very thick (larger than 2 μm). This entails numerous problems. Thus for example large distortions and cracks can be produced in the component.

It is the object of the present invention to overcome the disadvantages of the state of the art and in particular to make possible a simple, reliable production but to ensure, at the same time, sufficient mechanical stability which endures in particular the stresses occurring during bonding or soldering.

This object is achieved by the electronic component according to claim 1 and also by the method for production of an electronic component according to claim 11. Advantageous developments of the electronic component and of the method according to the invention are given in the respective dependent claims.

An electronic component according to the invention has firstly a contact surface which is situated in a contact plane. The contact surface can be for example the surface of an active zone or a surface of a metallisation or layer on such an active zone of a semiconductor component. In general, the contact surface is that region or that surface to which an electrical contact is intended to be produced via a bonding contact and/or a soldering contact.

The electronic component has furthermore an insulating layer which is situated on, over or above the contact surface and/or the contact plane. If a direction perpendicular to the contact surface is defined as above, then this means that the insulating layer is disposed further above than the contact surface. It is possible, but not necessary, that the insulating layer is disposed also above a part of the contact surface, which means that a perpendicular projection of the insulating layer falls on the contact plane on a part of the contact surface. The insulating layer can however also end precisely above the edge of the contact surface and be present only where it is not situated above the contact surface.

At least one stabilising layer is now disposed according to the invention on and/or above the at least one insulating layer. The stabilising layer is preferably disposed directly on the insulating layer.

According to the invention, at least one opening is provided which extends through the insulating layer and the stabilising layer as far as the contact surface. These openings correspond therefore to openings in the insulating layer and openings in the stabilising layer which are disposed thereabove. A through-direction of the opening is preferably perpendicular to the contact surface.

The component according to the invention has in addition at least one bonding contact and/or one soldering contact which extends above and/or on the stabilising layer and extends through the at least one opening as far as the contact surface and touches this and contacts it electrically.

The bonding or soldering contact therefore covers at least a partial region of a surface or upper side of the stabilising layer and in addition covers the contact surface at least in regions. An underside of the bonding contact or of the soldering contact, orientated towards the contact surface, preferably follows the surface of the layers situated directly thereunder, i.e. the surface of the stabilising layer, the side walls in the interior of the opening and also the contact surface.

At least one bonding wire or a soldering wire can then be applied on a surface of the bonding contact or of the soldering contact which is orientated away from the contact surface.

The arrangement according to the invention makes it possible to place bonding surfaces or soldering surfaces of an electronic component over an active zone, i.e. the contact surface. The insulating layer thereby ensures insulation between the contact surface or active zone and the bonding surfaces or the soldering surfaces. On the other hand, the opening enables through-contacting of the contact surfaces, for example on an active zone, to the associated bonding surfaces or soldering surfaces through the insulating or dielectric layer and the stabilising layer. The stabilising layer ensures the mechanical stability which is necessary in order to be able to apply bonding wires or soldering wires to the bonding surfaces or soldering surfaces.

Both the insulating layer and the stabilising layer can be layer systems having a large number of layers. However, they can also have or be respectively only one layer.

Advantageously, in particular if the insulating layer is disposed above the contact surface at least in regions, at least one passivating layer or a passivating layer system is disposed between the insulating layer and the contact surface, which passivating system particularly preferably separates the contact surface entirely from the insulating layer. The mentioned opening extends in this case also through the passivating layer or the passivating layer system so that the bonding contact or soldering contact is in contact with the contact surface.

Preferably, the passivating layer is disposed directly on the contact plane or contact surface and/or the insulating layer directly on the passivating layer or on the contact plane or surface. In addition, the stabilising layer is preferably disposed directly on the insulating layer.

The bonding contact or soldering contact is preferably disposed directly on the mentioned stabilising layer, opening wall and/or contact surface situated thereunder.

A layer thickness of the insulating, i.e. dielectric layer, is preferably ≧100 nm, preferably ≧120 nm, particularly preferred ≧200 nm, particularly preferred 300 nm and/or ≦600 nm, preferably ≦500 nm, particularly preferred ≦400 nm.

Preferably, the at least one opening is designed such that its cross-sectional area and/or its diameter increases towards the top starting from the contact surface, preferably strictly monotonously and steadily. For this purpose, the walls of the opening can be inclined outwardly at an angle to the contact plane of <90°. The walls hereby stand for instance in the shape of a funnel and/or the sides of the opening can be positive or have a positive profile.

As a result of the fact that the cross-sectional area of the opening increases towards the top, it can be ensured that the opening is filled completely with the material of the bonding contact or of the soldering contact when producing the bonding contact or the soldering contact, or a laminar bonding or soldering contact abuts against a wall of the opening without holes forming between the wall and the bonding contact or soldering contact.

The cross-sectional area of the opening can be made circular, rectangular, square or in other shapes.

Preferably, a hardness of the material of the stabilising layer is greater than a hardness of the material of the insulating layer. It is consequently achieved that the stabilising layer leads to an overall more stable layer system than would be the case without a stabilising layer with only the insulating layer.

Possible materials of the dielectric layer or of a dielectric layer system are inorganic materials, such as SiN, SiO₂, metal oxides, metal nitrides, Al₂O₃, TiO₂, TiO₃, on the one hand, but also, on the other hand, organic and/or polymer-based materials, such as benzocyclobutenes (BCB).

BCB has the advantage that it is present as a solution/liquid and, like e.g. a photoresist, can be centrifuged onto the samples and then baked. Therefore high-quality dielectric and insulating layers which are several micrometers thick can be produced relatively easily. No complex units are required for the deposition, such as for example with SiO₂ or SiN. The structuring/etching is preferably effected analogously to the other dielectric layers. A further advantage of BCB is that it has a smoothing effect because of the application and the general properties of BCB. Any height difference in the process topology is smoothed out after the BCB process. Since BCB is elastic, it produces no internal stresses.

It is problematic in the use of polymer-based materials for the dielectric layer that these are mechanically less stable than inorganic materials, which makes the application of the bonding wires or soldering wires on the bonding surfaces or soldering surfaces difficult or impossible. A good connection between bonding wire or soldering wire and bonding surface or bonding pad (soldering surface or soldering pad) requires in fact that the wires are applied on the bonding layer or soldering layer with sufficiently high pressure. If the insulating layer is deformed plastically, as is the case with polymer-based materials, then the connection between wire and surface is produced only incompletely or not at all.

The stabilising layer according to the invention resolves this problem. The stabilising layer which is preferably made of a harder material than the insulating layer is hereby applied over the possibly plastically deformable material of the insulating layer. The application can hereby be effected directly after the thermal stabilisation of the plastically deformable material. The deposition temperature of the stabilising layer can thereby exceed a curing temperature of the insulating layer.

The stabilising layer can include for example SiN and/or SiO₂ or consist thereof. Also a possibly present passivating layer can include SiN and/or SiO₂ or consist thereof.

Preferably, the electronic component according to the invention is a semiconductor component. The invention can be applied for all known semiconductor components. However, it can be applied for particular preference on semiconductor components which have at least one nitride or a group-III-substance, particularly preferred GaN, since these are used above all in power electronics where numerous components can be contacted in parallel in a space-saving manner by means of the vertical contacting according to the invention.

The component according to the invention can be a component with one, two, three or more contacts. A contact surface which can be contacted by respectively one bonding contact and/or soldering contact thereby corresponds to one contact respectively. However, also a plurality of contact surfaces can be contacted by means of a common bonding contact and/or soldering contact if they have a similar function or are intended to be connected electrically. A separate opening in the layers disposed above the contact surface is preferably supplied for each contact surface.

The component according to the invention can particularly advantageously be a diode with two contacts or contact surfaces which are contacted via two bonding contacts and/or soldering contacts which are insulated electrically relative to each other. The component according to the invention can also be a transistor with three contacts, namely drain, gate and source, which are contacted respectively via a separate bonding contact or soldering contact.

The insulating layers of the component can be produced for particular preference via one or more of the following processes: chemical deposition (CVD), plasma-enhanced chemical deposition (PECVD), mechanical processes, such as cathode sputtering, sputtering or other thermal processes, such as e.g. vaporisation or others, also by means of centrifuging or spraying. Also a possibly present passivating layer can be applied by means of these processes.

During the production of the component according to the invention, the described openings are preferably produced before application of the bonding contacts or soldering contacts. Such openings can be effected through the stabilising layer and the insulating layer particularly preferably by means of one or more processes selected from the processes of reactive ion etching, physical removal of the corresponding layer, inductively-coupled plasma etching and/or vaporisation of the corresponding material by means of laser light.

In the production of the openings, as described above, a profile is preferably produced which ensures that the openings can be filled or coated with the bonding or soldering contact in particular on the side faces thereof without gaps. As described, the profile of the holes should be a positive profile for this purpose, i.e. the hole diameter increases from below the opening up to above the opening.

After completion of the openings, these are filled with the material of the corresponding bonding or soldering contact or the side faces of the openings and their base which is normally formed by the contact surface is coated with the material of the contact, the coating of the opening wall being in electrical contact with a corresponding coating with the material of the bonding or soldering contact on the surface of the stabilising layer and preferably being configured continuously with this.

The described profile of the openings with non-perpendicular side walls can be adjusted by suitable choice of the process parameters, such as suitable choice of the gas, pressure, gas flow, acceleration voltage, HF power and/or the power of an inductively-coupled plasma. For the production of such openings, multistage etching processes are particularly suitable, the layer situated thereunder after etching of the uppermost layer being etched such that, during this step, the upper layer is further etched so that the layers situated uppermost are etched most during further penetration of the etching process into the layer system and a layer situated further above is respectively further etched than a layer situated further down. In this way, an opening, the opening surface of which reduces towards the bottom, is produced.

During production, specific parameters of the process can be varied in order to achieve the desired functionality of the insulating layer and of the stabilising layer. In particular, plant-specific variations of the production parameters are hereby possible, such as gas flows, gas partial pressures, ICP powers, IRE powers, process temperatures etc. It is also possible to vary the composition of the gases which are used provided that the results achieved in the process are comparable. It is hereby particularly advantageous if the reactive component of the molecules, such as for example fluorine, is present furthermore in the varied gases (e.g. reversion of CF₄ to CₓF_{y}) and similarly can be broken down in the plasma, preferably with comparable with RF power, process temperature and gas pressure, into its individual components (i.e. carbon and fluorine here).

For production of the system according to the invention, the passivating layer can firstly be deposited and then structured. The dielectric layer, e.g. made of BCB, and then the stabilising layer can be applied subsequently. Thereafter the openings can be etched.

However, a method is preferred where firstly the passivating layer is deposited but not structured. Subsequently, the dielectric layer and the stabilising layer are applied. Thereafter, the openings are produced through all three layers, e.g. etched. The production of the openings can be effected by means of a three-stage dry etching process which etches firstly the stabilising layer, then the insulating (dielectric) layer and finally the passivating layer.

The production process can be achieved also by using individual processes. The described profile of the openings can be produced in a plurality of independent individual processes, for example each individually applied layer being structured and etched individually. After applying the insulating layer, this can thus be structured by means of temporarily applied, for example lithographically structurable, layers for the layout specification with subsequent etching of the layer and the stabilising layer in the corresponding manner. The temporary masking layer is thereby removed before applying the layer of the semiconductor component situated thereabove.

It is furthermore also possible that the layers of the component according to the invention are themselves photo-sensitive, as is the case for example with BCB. In this case, the layers themselves can be structured by means of lithography processes. For example, the insulating layer can have a photo-sensitive BCB which is then structured by means of lithography in order to produce a suitable opening with a suitable profile. In the next step, the stabilising layer, for example made of SiN, is applied over the entire surface and a lithographicially structured photoresist is applied temporarily. In a dry etching process, the stabilising layer can now be etched such that suitable inclined opening walls result.

The component according to the invention can preferably be a two-port component or a three-port component, such as e.g. a diode or a transistor. However it can also be a complex semiconductor component, such as is used for example in power electronics. Group-III-nitride-based diodes and transistors can be produced particularly advantageously. In particular for the production of energy-efficient systems, group-III-nitride-based Schottky diodes and transistors which have the construction according to the invention display low power loss and hence significant advantages. Diodes and transistors of this type can be used for example in high-frequency combinational circuit parts, in efficient convertors in hybrid motive power technology or in solar technology.

The invention is intended to be explained subsequently by way of example with reference to a few Figures.

There are shown

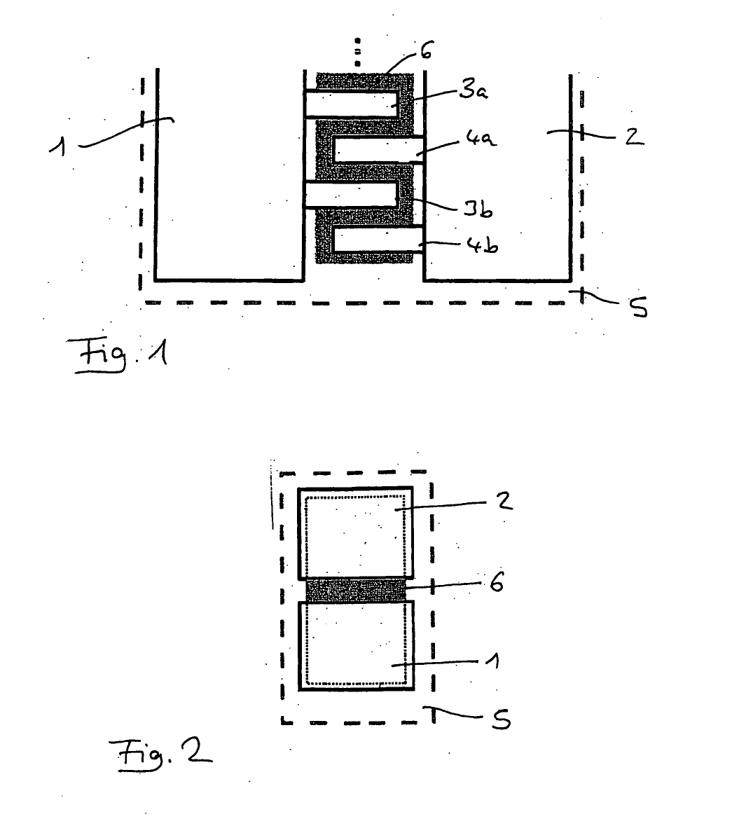

FIG. 1 a laterally contacted component in which the bonding surfaces or soldering surfaces are disposed laterally of an active zone,

FIG. 2 a vertically contacted component in which two bonding surfaces are disposed over an active zone,

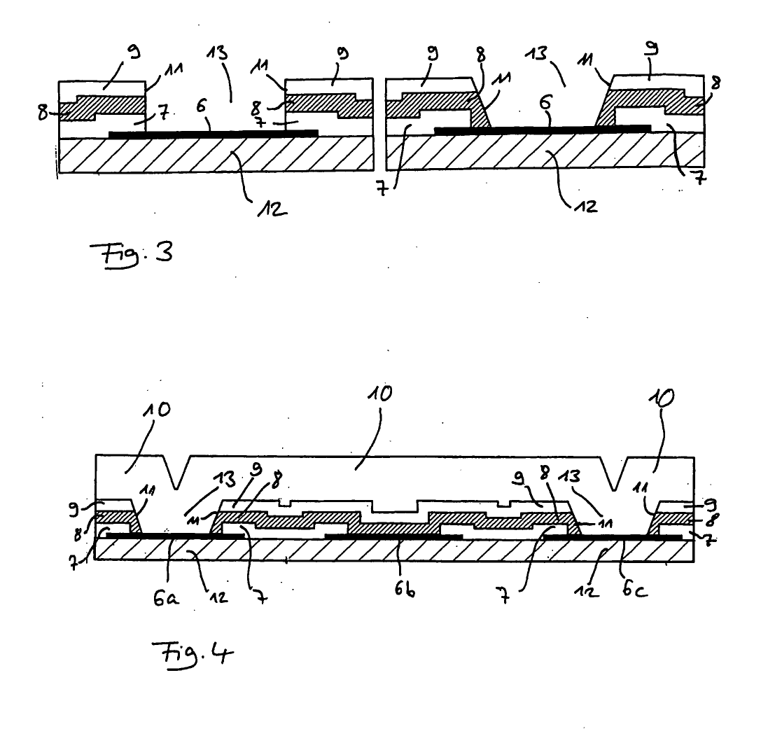

FIG. 3 a cross-section through two embodiments of a layer system, as can be used in the component according to the invention, and

FIG. 4 a component according to the invention having three contacts.

FIG. 1 shows a laterally contacted electronic component in which an active zone 6 is contacted by means of a first bonding and/or soldering surface 1 and a second bonding and/or soldering surface 2 which are disposed next to the active zone 6. As a result of the fact that the bonding surfaces 1 and 2 are not able to be disposed over the active zone 6, the entire surface of the component on a substrate 5 is determined by the sum of the bonding surfaces 1 and 2 and also the surface of the active zone 6. In the illustrated example, respectively bonding and soldering contacts can be produced analogously.

Between the active zone 6 and the bonding surface 1, an electrical contact is produced by the contacts 3a and 3b. Between the active zone 6 and the bonding surface 2, an electrical contact is produced by means of the contact surfaces 4a and 4b. The contact surfaces 3a, 3b, 4a, 4b end at a lateral edge of the corresponding bonding surface 1 or 2 and contact a contact surface of the active zone 6 from above. In the illustrated example, the contacts of the one bonding surface 1 are disposed interleaved with those contacts of the bonding surface 2.

FIG. 2 shows an alternative contacting of an active zone 6 via bonding surfaces 1 and 2, as can be used in the component according to the invention. The bonding surfaces 1 and 2 hereby cover the active zone 6 at least in regions. The bonding surfaces 1 and 2 are therefore disposed above the active zone 6 at least in regions. It can be detected that the surface area which is occupied by this arrangement on a substrate 5 and hence the surface area or size of the component per se can be designed to be significantly smaller than in the example shown in FIG. 1. An arrangement as is shown in FIG. 2 requires however a vertical contacting technique which makes it possible to connect the active zone 6 below the bonding surfaces 1 and 2 electrically to the bonding surfaces 1 and 2. For this purpose, the component can be configured according to the invention.

FIG. 3 shows two embodiments of a layer system, as can be present in the component according to the invention. In the left partial image, firstly a layer system is shown in which firstly a passivating layer 7 is disposed over a contact surface 6, on which passivating layer in turn a dielectric insulating layer 8 is disposed directly. On the insulating layer 8, a stabilising layer 9 is then directly disposed. In the illustrated example, the passivating layer 7 and the stabilising layer 9 is an SiN layer, whilst the dielectric layer 8 is a polymer layer made of BCB. Other materials for the passivating layer 7 and the stabilising layer 9 can be e.g. SiO₂. The insulation layer 8 can have for example inorganic materials, such as SiN, SiO₂ metal oxides, metal nitrides, Al₂O₃, TiO₂ and/or TiO₃.

In layers 7, 8 and 9, an opening 13 is now produced in the examples shown in FIG. 3, which opening can have been formed by reactive ion etching, physical removal of the material, inductively-coupled plasma etching, vaporisation by means of laser light or similar. Walls 11 of the opening are thereby perpendicular to the contact surface 6 in the left partial image, whilst, in the right partial image, they have a positive profile, i.e. include an angle <90° to the outside with the contact plane in which the contact surface 6 is situated. In the illustrated example, the contact surface 6 is not directly the surface of an active zone 12, rather a metal layer 6 is disposed on the surface of the active zone 12, the surface 6 of which metal layer, orientated away from the active zone 12, represents the contact surface.

In the left embodiment of FIG. 3, both the passivating layer 7 and the insulating layer 8 and the stabilising layer 9 abut against the opening 13 so that these three layers appear on the wall 11 of the opening. In contrast thereto, the wall 11 of the opening 13, in the right partial image, is formed only by the material of the stabilising layer 9 and of the insulating layer 8, the insulating layer 8 on the wall 11 of the opening 13 passing however also through the opening 13 in the passivating layer 7 and reaching as far as the contacting surface 6. The insulating layer 8 hereby is present therefore between the edge of the passivating layer 7, orientated towards the opening 13, and the opening 13.

Production of the layers 7, 8 and 9 is possible for example by means of chemical deposition (CVD), plasma-enhanced chemical deposition (PECVD), mechanical processes, such as cathode sputtering, sputtering and others, in particular thermal processes, such as vaporisation and similar, and also by means of centrifuging or spraying. Each of the layers 7, 8 and 9 can have an individual layer or be a multilayer system.

FIG. 4 shows a component according to the invention in which three contact surfaces 6a, 6b and 6c are contacted. There are disposed above the contact surfaces 6a and 6c, as shown in the right part of FIG. 3, firstly a passivating layer 7, thereupon an insulating layer 8 and on this a stabilising layer 9. The construction of the layer system corresponds to that shown in the right part of FIG. 3. Here also, the opening 13 is configured such that the cross-sectional area of the opening 13 enlarges to the top. In the component shown in FIG. 4, a bonding contact 10 is now deposited on the layer system. This bonding contact 10 extends over a surface of the stabilising layer 9, orientated towards the contact surface 6a, and also into the openings 13 so that it covers the inner walls 11 of the openings 13 and also the contact surfaces 6a or 6c completely. The component according to the invention can now be contacted via the bonding contact 10 from outside. For this purpose, one or more bonding wires can be fitted for example on that surface of the bonding contact 10 orientated away from the contact surfaces 6a, 6c.

The contact 6b is contacted at another location of the component. The production process is the same here as with the other contacts.

A deposition of the insulating layer 8 is intended to be explained subsequently by way of example. The example hereby relates to an AlGaN/GaN-based electronic component on silicon-saphire- or silicon-carbide substrates which is passivated with a silicon nitride layer. The illustrated production process should be understood as being by way of example and also other production processes are conceivable.

In a first step, the silicon nitride is deposited at a temperature of 340° C., a pressure of 0.6 mTorr, a power of 40 W, and also gas flows of 71 sccm silane and 900 sccm nitrogen in an Oxford Plasmalab 80 Plus PECVD unit. The deposited layer is structured with the help of a dry etching step. In an Oxford Plasmalab 100 ICP unit, openings are etched at a pressure of 25 mTorr, an ICP power of 500 W, an HF power of 20 W, an SF₆ flow of 40 sccm and an O₂ flow of 6 sccm.

Subsequently, a resin (BCB, cyclotene) is centrifuged at 4,000 (or 2,000 or 6,000) revolutions and baked at 70° C. on a hot plate. The resin is thermally stabilised in a furnace at 250° C. for 60 minutes.

In order to increase the mechanical stability, a silicon nitride layer is deposited on the resin at a temperature of 340° C., a pressure of 0.6 mTorr, a power of 40 W, and also gas flows of 71 sccm silane and 900 sccm nitrogen in an Oxford Plasmalab 80 Plus PECVD unit. The achieved layer thickness is between 200 and 500 nm as a function of the process duration.

The above layer thicknesses allow sufficient mechanical stability which enables application of bonding wires with sufficient tensile strength.

One possibility for producing the opening 13 is now intended to be described subsequently by way of example.

With the help of a two-stage dry etching process in an Oxford Plasmalab 100 ICP unit, contact openings are firstly etched into the silicon nitride layer and then into the resin. In the first step, etching takes place in an ICP unit at a pressure of 25 mTorr, an ICP power of 500 W, an HF power of 20 W, an SF₆ flow of 40 sccm and an O₂ flow of 8 sccm. In the second step, the resin is then etched with the following parameters: the pressure is 30 mTorr, the ICP power 1,000 W, the HF power 50 W, an SF₆ flow 10 sccm and an O₂ flow 50 sccm.

It is ensured by this etching process that the openings have positive sides and hence no regions are produced which are shaded in the following metallisation step. As a result, the side walls of the openings can be vapour-coated completely with metal and filled completely with metal by galvanic deposition. The bonding pads are produced at the same time with these metallisation steps.

1. An electronic component having at least one contact surface situated in a contact plane, at least one insulating layer disposed above the contact plane, at least one stabilizing layer disposed on the insulating layer for increasing a mechanical stability of the component, and at least one of a bonding contact and a soldering contact, the insulating layer and the stabilizing layer having at least one opening which opens in an upper side of the stabilizing layer, the upper side of the stabilizing layer being oriented away from the contact surface and the opening extending through the stabilizing layer and the insulating layer as far as the contact surface, and the at least one of a bonding contact and a soldering contact extending over the stabilizing layer and touching the contact surface through the opening.

2. An electronic component according to claim 1 wherein the insulating layer is disposed at least in some regions over the contact surface and wherein at least one passivating layer is disposed between the insulating layer and the contact surface, the opening extending through the passivating layer.

3. An electronic component according to claim 1 wherein a cross-sectional area of the opening is reduced in the direction from the upper side of the stabilizing layer towards the contact surface.

4. An electronic component according to claim 1 wherein the at least one of the bonding contact and the soldering contact at least one of completely fills the opening and is configured as layer on at least one part of an inner wall of the opening and at least on one part of the contact surface.

5. An electronic component according to claim 1 wherein a hardness of the stabilizing layer is greater than a hardness of the insulating layer.

6. An electronic component according to claim 1 characterized by at least one of the following: the passivating layer comprises at least one of SiN and SiO₂; and the insulating layer comprises at least one of organic materials, benzocyclobutenes, SiN, SiO₂, metal oxides, metal nitrides, Al₂O₃, TiO₂ and TiO₃.

7. An electronic component according to claim 1 wherein the electronic component is a semiconductor component.

8. An electronic component according to claim 1 wherein the electronic component has at least two contact surfaces, an opening being disposed above each of the contact surfaces, and characterized by at least one of the following: a plurality of contact surfaces is contacted by at least one of a common bonding contact and a common soldering contact; and all of the contact surfaces are contacted by at least one of separate bonding contacts and separate soldering contacts.

9. An electronic component according to claim 1 characterized by at least one of the following: the bonding contacts comprise bonding surfaces which are disposed with surfaces parallel to the corresponding contact surface over the corresponding contact surface; and the soldering contacts comprise soldering surfaces which are disposed with surfaces parallel to the corresponding contact surface over the corresponding contact surface.

10. An electronic component according claim 1 wherein the electronic component is one of a diode and a transistor.

11. A method for the production of an electronic component having at least one contact surface situated in a contact plane, at least one insulating layer disposed above the contact plane, at least one stabilizing layer disposed on the insulating layer for increasing a mechanical stability of the component, and at least one of a bonding contact and a soldering contact, the insulating layer and the stabilizing layer having at least one opening which opens in an upper side of the stabilizing layer, the upper side of the stabilizing layer being oriented away from the contact surface and the opening extending through the stabilizing layer and the insulating layer as far as the contact surface, and the at least one of a bonding contact and a soldering contact extending over the stabilizing layer and touching the contact surface through the opening, the method comprising first applying the at least one insulating layer over the contact plane, then applying the at least one stabilizing layer, and then producing the at least one opening.

12. The method according to claim 11 further comprising applying the at least one passivating layer before application of the insulating layer.

13. The method according to claim 12 further comprising structuring the passivating layer before application of the insulating layer.

14. The method according to claim 12 further comprising applying the insulating layer before structuring the passivating layer and producing the opening through all applied layers after applying the stabilizing layer.

15. The method according to claim 11 further comprising producing the at least one insulating layer from a curable plastically deformable material and applying the at least one stabilizing layer at a deposition temperature which exceeds a curing temperature of the insulating layer.

16. The method according to claim 11 further comprising applying at least one of the at least one insulating layer and the at least one stabilizing layer by at least one of: chemical deposition (CVD); plasma-enhanced chemical deposition (PECVD); a mechanical process; cathode sputtering; sputtering; vaporization; centrifuging; and spraying.

17. The method according to claim 11 comprising beginning on an upper side of the component oriented away from the contact plane and removing material successively so that the removal progresses in the direction perpendicular to the surface and so that removal of material progresses from a lesser depth of the resulting opening to a greater depth so that a cross-sectional area of the opening reduces in the direction of the contact plane with increasing depth.

18. The method according to claim 11 comprising producing the at least one opening by at least one of: reactive ion etching; physical removal; inductive-coupled plasma etching; and vaporization by laser light.

19. An electronic component according to claim 2 wherein a cross-sectional area of the opening is reduced in the direction from the upper side of the stabilizing layer towards the contact surface.

20. An electronic component according to claim 2 wherein the at least one of the bonding contact and the soldering contact at least one of completely fills the opening and is configured as layer on at least one part of an inner wall of the opening and at least on one part of the contact surface.
